(19) United States
(12) Patent Application Publication
(10) Pub. No.: US 2014/0110157 A1
(43) Pub. Date: Apr. 24, 2014

(54) Printed Circuit Board Module and Module Side Wall

(71) Applicant: Tian Zhang, Shenzhen City (CN)

(72) Inventor: Tian Zhang, Shenzhen City (CN)

(73) Assignee: Shenzhen China Star Optoelectronics Technology Co., Ltd., Shenzhen, Guangdong (CN)

(21) Appl. No.: 13/700,490

(22) PCT Filed: Oct. 30, 2012
(86) PCT No.: PCT/CN2012/083757

§ 371 Date: Nov. 28, 2012

(30) Foreign Application Priority Data
Oct. 24, 2012 (CN) 201210410020.7

(51) Int. Cl. H05K 1/02

(52) U.S. Cl. CPC H05K 1/0277
USPC 174/254

(57) ABSTRACT

The present invention discloses a PCB module, including PCB, side board, importing part and stop wall. The PCB module is for fixing PCB to the module. The present invention also discloses a module side wall, including side board, importing part and stop wall. The fixing structure of the present invention is simple and utilizes the flexibility of PCB to guide and fix PCB onto module side wall. The present invention can save the tedious operation of fixing PCB process in known techniques and improve production efficiency.

### BACKGROUND OF THE INVENTION

1. Field of the Invention

The present invention relates to the field of printed circuit board (PCB) assembly techniques, and in particular to a PCB module and module side wall.

2. The Related Arts

In the digital era, electronic products become ubiquitous in every aspect of life. The electronic devices, such as, PC, mobile device, camera and electronic photo frame, and so on, usually comprise printed circuit board (PCB) for electrical connection.

The fixing of PCB is an important step in module design. FIG. 1 is a schematic view showing the structure of a known technique for fixing PCB to one side of a module. PCB 1 is fixed to one side of a module 2 through a certain means. A good PCB fixing means does not only improve assembly efficiency and reduce the use of chop on film (COF), but also can rapidly pass the reliability test of vibration impact and improve product reliability.

The current OCB fixing means includes:

1. through connectors, such as, coupling bolt or screw, to fix the PCB directly to the side of the module. However, the use of connectors to fix is inefficient and not suitable for an assembly line manufacturing because of the location restriction when operating at one side of the module.

2. constructing a trench on the module mold frame, and then using an iron frame to cover up after placing the PCB. Although the efficiency is high for this approach, the PCB is not tightly fixed and may lead to poor bonding and result in display problem, such as, unclear display.

3. using auxiliary element to position, such as buckle, and then using tape to attach the PCB to the back or side of the module. The operations of this approach are complicated and have potential problem of grounding and reliability.

### SUMMARY OF THE INVENTION

The technical issue to be addressed by the present invention is to provide a PCB module, able to solve the problem of low efficiency for PCB fixing and complicated PCB fixing structure in known techniques.

The present invention provides a PCB module, which comprises: a PCB, with flexibility; a side board: an importing part, disposed on a first side of the side board: the importing part comprising: a stop block, forming a slant surface at inner side of the top; an importing trench, formed between the stop block and the side board for guiding the PCB into the importing trench along the slant surface; a stop wall, disposed on a second side of the side board, the first side and the second side being oppositely disposed; wherein the importing part and the stop wall collaborating and using flexibility of PCB to limit and stick the PCB onto the side board; a first press part and a second press part, disposed respectively on a third side and a fourth side of the side board, the third side and the fourth side being oppositely disposed for pressing against the PCB.

According to a preferred embodiment of the present invention, a width of the importing trench is the same as a thickness of the PCB.

According to a preferred embodiment of the present invention, the stop wall and the importing part are disposed interleavingly.

The present invention provides a PCB module, which comprises: a PCB, with flexibility; a side board; an importing part, disposed on a first side of the side board; a stop wall, disposed on a second side of the side board, the first side and the second side being oppositely disposed; wherein the importing part and the stop wall collaborating and using flexibility of PCB to limit and stick the PCB onto the side board.

According to a preferred embodiment of the present invention, the PCB module further comprises a first press part and a second press part, disposed respectively on a third side and a fourth side of the side board, the third side and the fourth side being oppositely disposed for pressing against the PCB.

According to a preferred embodiment of the present invention, the importing part comprises: a stop block, forming a slant surface at inner side of the top; an importing trench, formed between the stop block and the side board for guiding the PCB into the importing trench along the slant surface.

According to a preferred embodiment of the present invention, a width of the importing trench is the same as a thickness of the PCB.

According to a preferred embodiment of the present invention, the stop wall and the importing part are disposed interleavingly.

The present invention provides a module side wall, which comprises: a side board; an importing part, disposed on a first side of the side board; a stop wall, disposed on a second side of the side board, the first side and the second side being oppositely disposed; wherein the importing part and the stop wall are disposed interleavingly for clamping an object.

According to a preferred embodiment of the present invention, the PCB module further comprises a first press part and a second press part, disposed respectively on a third side and a fourth side of the side board, the third side and the fourth side being oppositely disposed for pressing against the PCB.

According to a preferred embodiment of the present invention, the importing part comprises: a stop block, forming a slant surface at inner side of the top; an importing trench, formed between the stop block and the side board for guiding the PCB into the importing trench along the slant surface.

According to a preferred embodiment of the present invention, a width of the importing trench is the same as a thickness of the PCB.

According to a preferred embodiment of the present invention, the stop wall and the importing part are disposed interleavingly.

The efficacy of the present invention is that to be distinguished from the state of the art. The PCB module comprises PCB, side board, importing part and stop wall. The PCB module is for fixing PCB to the module. The structure is simple and utilizes the flexibility of PCB to guide and fix PCB onto module side wall. The present invention can save the tedious operation of fixing PCB process in known techniques and improve production efficiency.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the structure of a known technique for fixing PCB to one side of a module;

FIG. 2 is schematic view showing the dissected structure of the PCB module of an embodiment according to the present invention;

FIG. 3 is an enlarged view showing the structure of importing part and the peripheral in FIG. 2:

FIG. 4 is a schematic view showing the bending when fixing PCB in FIG. 2;

FIG. 5 is a schematic view showing the assembly of PCB module of an embodiment of the present invention;

FIG. 6 is a schematic view showing the X, Y Z directions of PCB in FIG. 2; and

FIG. 7 is a schematic view showing the deformation of PCB of FIG. 2 in X direction due to flexibility.

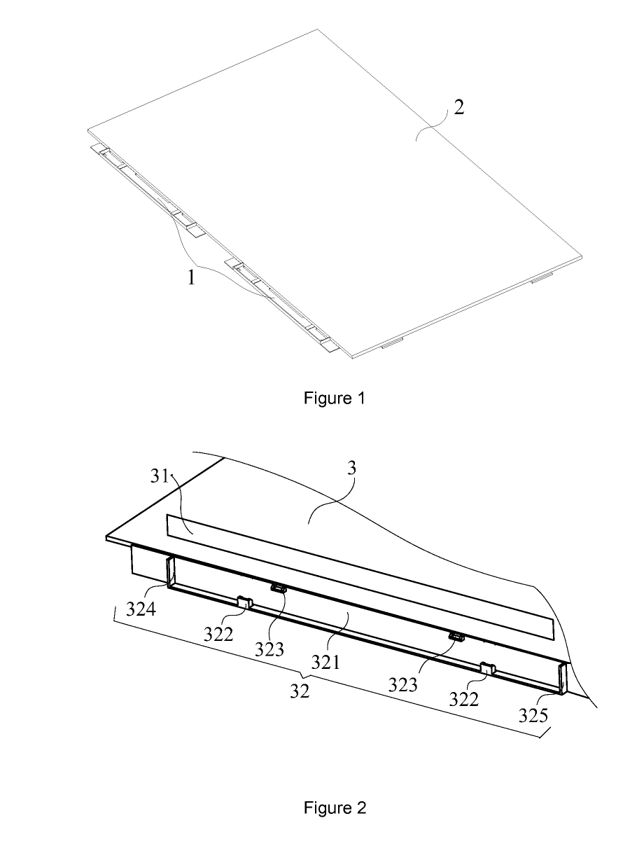

### DETAILED DESCRIPTION OF THE PREFERRED EMBODIMENTS

The following provides a clear and complete description of the technical solution according to the present invention using the drawing and the embodiment. Apparently, the drawings described below show only example embodiments of the present invention, instead of all embodiments. For other embodiments based on the disclosed drawings and embodiments, and obtained by those having ordinary skills in the art without paying any creative effort are also within the scope of the present invention.

The following embodiment discloses a PCB module. Referring to FIG. 2, FIG. 2 is schematic view showing the dissected structure of the PCB module of an embodiment according to the present invention. The PCB module is for fixing a PCB 31, which comprises: a PCB 31, with flexibility; a side board 321; an importing part 322 and a stop wall 323. In an exemplary embodiment, the PCB 31 is a long stripe with a length of 46 inches and a width of 2 inches. The PCB 31 is flexible. The side board 321 is a board of a module side wall 32 of the module 3. The side board 321 has a length larger than the length of the PCB 31, and a height slightly taller than the width of the PCB 31 for convenient disposition of stop wall 323. The importing part 322 is disposed on a first side of the side board 321, that is, the lower side shown in FIG. 2. When processing, the importing part 322 and the side board 321 can be formed monolithically. The importing part 322 is for stick PCB 31.

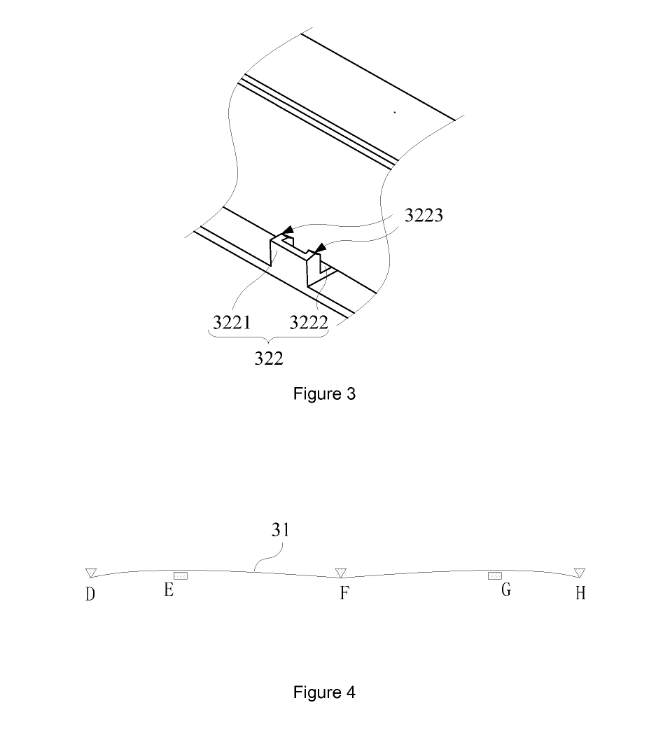

Referring to FIG. 3, FIG. 3 is an enlarged view showing the structure of importing part and the peripheral in FIG. 2. The importing part 322 further comprises a stop black 3221 and an importing trench 3222. The stop block 3221 extends from bottom of the side board 321 and bends upwards. A slant surface 3223 is formed on inner side of the stop of the stop block 3221. The slant surface 3223 is for guiding PCB 31 into the module side wall 32 along the slant surface 3223. The importing trench 3222 is formed between the stop block 3221 and the side board 321. The importing trench has a width matching the thickness of the PCB 31 for accommodating PCB 31. In the instant embodiment, there are two importing parts 322. In other embodiments, the number of importing parts 322 can vary according to the length of the PCB 31. The stop wall 323 is disposed on a second side of the side board 321, the first side and the second side being oppositely disposed, shown as the upper side in FIG. 2. The importing part 322 at the upper side and the stop wall 323 at the lower side can be disposed interleavingly. In other words, the importing parts 322 and the stop walls 323 are not at the same vertical level and are apart with fixed interval horizontally. For firm installation, the heights of importing part 322 and stop wall 323 is slightly less than the thickness of PCB 31, such as, 0.1-0.2 mm less. In the instant embodiment, the stop wall 323 and the side board 321 can be formed monolithically, and there are two stop walls 323. In other embodiments, the number of stop walls 323 can vary according to the length of the PCB 31. However, when the number of stop walls 323 is too many, the difficulty of assembling the PCB 31 will increase and reduce the efficiency. By utilizing the flexibility of PCB 31, the importing part 322 and the stop wall 323 collaborate to limit and stick the PCB 31 onto the side board 321.

Also referring to FIG. 2, the PCB module further comprises a first press part 324 and a second press part 325, disposed respectively on a third side and a fourth side of the side board 321 The third side and the fourth side are oppositely disposed. The first press part 324 has the same structure as the second press part 325, and is a protruding board perpendicular to the side board 321 with a width larger than the thickness of the PCB 31. The present invention utilizes the flexibility of PCB 31 and uses the first press part 324 and the second press part 325 to press against the PCB 31. For better pressing result, the length of PCB 31 is preferably larger than the distance between the first press part 324 and the second press part 325 by 2-4 mm.

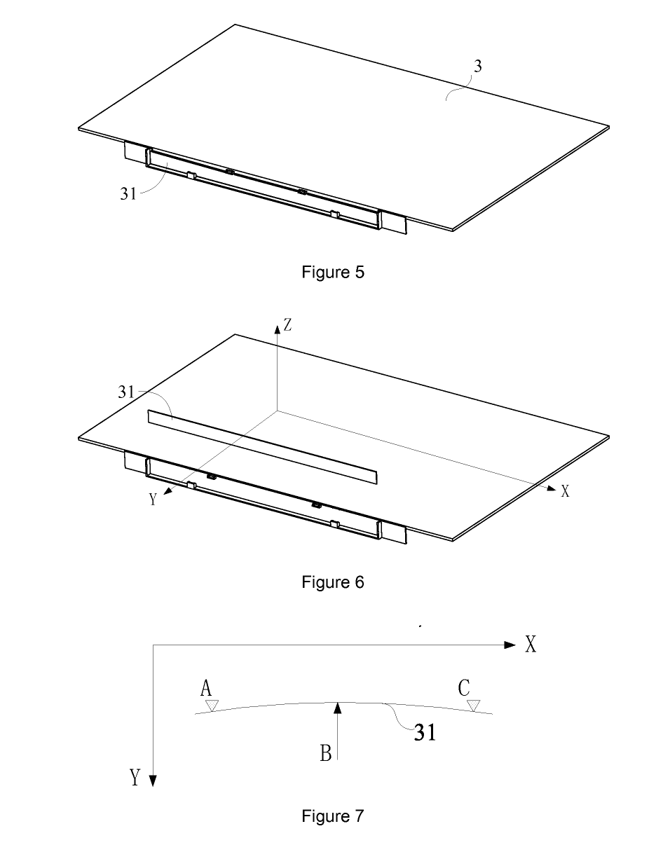

When fixing PCB 31, the PCB 31 is held in parallel with the side board 321 in the length direction and is guided into importing trench 3222 along the slant surface 3223 at the top of stop block 3221, as shown in FIG. 4. FIG. 4 is a schematic view showing the bending when fixing PCB in FIG. 2, wherein E and G are the contact points of PCB 31 and importing part 322, is located in the middle of E and G, and D and H are two ends of the PCB 31. Pressing outwards the F of PCB 31, the E and G will bend inwards because PCB is supported by importing part 322. When fixing PCB 31, the PCB must be steered clear of stop wall 323 and placed between the first press part 324 and the second press part 325. Because the length of PCB 31 is less than the distance between the first press part 324 and the second press part 325 by 2-4 mm, the PCB 31 is tightly stuck onto module side wall 32. At the same time, a small deformation occurs in the width direction of PCB 31. Therefore, PCB 31 is stuck between the importing part 322 and the stop wall 323. FIG. 5 is a schematic view showing the assembly of PCB module of an embodiment of the present invention, wherein the PCB 31 is fixed onto one side of module 3.

The present invention utilizes the flexibility of the PCB and treats the PCB as a flexible element to assemble onto the module. Referring to FIG. 6, FIG. 6 is a schematic view showing the X, Y Z directions of PCB in FIG. 2. In X direction, the PCB 31 is a long stripe and therefore is prone to deformation in the X direction. The deformation in the Z direction is very small. By utilizing the deformation of PCB 31, the PCB 31 can be treated as a flexible object. Therefore, by applying force to limit the PCB 31 in the X direction(length), Y direction (thickness) and X direction (width), the PCB 31 can be fixed to locations set in the X, Y, Z directions without becoming loose.

Referring to FIG. 7, FIG. 7 is a schematic view showing the deformation of PCB of FIG. 2 in X direction due to flexibility. In the X direction of PCB 31, B is the middle point of A and C. When a force is applied to B, PCB 31 is deformed slightly. For a PCB of length 500 mm, the deformation at B is about 0.4-0.8 mm.

The present invention also discloses a module side wall. Referring to FIG. 2, a module side wall 32 comprises side board 321, importing part 322 and stop wall 323. The side board 321, importing part 322 and stop wall 323 are the same as described in above embodiments, and will not be repeated here.

As such, the PCB module comprises PCB, side board, importing part and stop wall. The PCB module is for fixing PCB to the module. The structure is simple and utilizes the flexibility of PCB to guide and fix PCB onto module side wall. The present invention can save the tedious operation of fixing PCB process in known techniques and improve production efficiency.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A printed circuit board (PCB) module, which comprises:
a PCB, with flexibility;
a side board;
an importing part, disposed on a first side of the side board; the importing part comprising: a stop block, forming a slant surface at inner side of the top; an importing trench, formed between the stop block and the side board for guiding the PCB into the importing trench along the slant surface;
a stop wall, disposed on a second side of the side board, the first side and the second side being oppositely disposed; wherein the importing part and the stop wall collaborating and using flexibility of PCB to limit and stick the PCB onto the side board;
a first press part and a second press part, disposed respectively on a third side and a fourth side of the side board, the third side and the fourth side being oppositely disposed for pressing against the PCB.

2. The PCB module as claimed in claim 1, characterized in that a width of the importing trench is the same as a thickness of the PCB.

3. The PCB module as claimed in claim 1, characterized in that the stop wall and the importing part are disposed interleavingly.

4. A printed circuit board (PCB) module, which comprises:
a PCB, with flexibility;
a side board;
an importing part, disposed on a first side of the side board;
a stop wall, disposed on a second side of the side board, the first side and the second side being oppositely disposed;
wherein the importing part and the stop wall collaborating and using flexibility of PCB to limit and stick the PCB onto the side board.

5. The PCB module as claimed in claim 4, characterized in that the PCB module further comprises a first press part and a second press part, disposed respectively on a third side and a fourth side of the side board, the third side and the fourth side being oppositely disposed for pressing against the PCB.

6. The PCB module as claimed in claim 4, characterized in that the importing part comprises:
a stop block, forming a slant surface at inner side of the top;
an importing trench, formed between the stop block and the side board for guiding the PCB into the importing trench along the slant surface.

7. The PCB module as claimed in claim 6, characterized in that a width of the importing trench is the same as a thickness of the PCB.

8. The PCB module as claimed in claim 4, characterized in that the stop wall and the importing part are disposed interleavingly.

9. A module side wall, which comprises:
a side board;
an importing part, disposed on a first side of the side board;
a stop wall, disposed on a second side of the side board, the first side and the second side being oppositely disposed;
wherein the importing part and the stop wall are disposed interleavingly for clamping an object.

10. The module side wall as claimed in claim 9, characterized in that the PCB module further comprises a first press part and a second press part, disposed respectively on a third side and a fourth side of the side board, the third side and the fourth side being oppositely disposed for pressing against the PCB.

11. The module side wall as claimed in claim 9, characterized in that the importing part comprises:
a stop block, forming a slant surface at inner side of the top;
an importing trench, formed between the stop block and the side board for guiding the PCB into the importing trench along the slant surface.

12. The module side wall as claimed in claim 11, characterized in that a width of the importing trench is the same as a thickness of the PCB.

13. The module side wall as claimed in claim 9, characterized in that the stop wall and the importing part are disposed interleavingly.
